(19) United States
(12) Patent Application Publication
(10) Pub. No.: US 2026/0071972 A1
(43) Pub. Date: Mar. 12, 2026

(54) LITHOGRAPHIC APPARATUS, METROLOGY SYSTEMS FOR CONTROLLING OPTICAL ABERRATIONS, AND METHOD THEREOF

(71) Applicant: ASML Netherlands B.V., Veldhoven (NL)

(72) Inventors: Changsik YOON, Waalre (NL); Armand Eugene Albert KOOLEN, Nuth (NL); Jasper Niko Maria HOOGVELD, Tilburg (NL); Adel JOOBEUR, Milford, CT (US); Richard Carl ZIMMERMAN, Brookfield, CT (US); Alexander Kenneth RAUB, Bethel, CT (US); Yuwei JIN, Eindhoven (NL); Su-Ting CHENG, Eindhoven (NL); Vasco Tomas TENNER, Amsterdam (NL); Xukang WEI, Valkenswaard (NL); Louise Karina Laurie GOUTEUX, Veldhoven (NL)

(73) Assignee: ASML Netherlands B.V., Veldhoven (NL)

(21) Appl. No.: 18/873,208

(22) PCT Filed: Jul. 25, 2023
(86) PCT No.: PCT/EP2023/070488

§ 371 Date: Dec. 9, 2024

Related U.S. Application Data
(60) Provisional application No. 63/399,966, filed on Aug. 22, 2022.
(60) Provisional application No. 63/512,677, filed on Jul. 10, 2023.

(51) Int. Cl. G01N 21/956; G02B 26/10; G03F 7/00

(52) U.S. Cl. CPC G01N 21/956; G03F 7/706; G03F 7/70633; G03F 7/706837; G03F 7/706845; G03F 7/706847; G03F 7/706849; G03F 7/706851; G01N 2021/95676; G02B 26/101

(57) ABSTRACT

A system includes an illumination system, a scanning system, an optical system, a detector system, and a processor. The illumination system directs an optical beam to illuminate a target structure. The scanning system scans the optical beam and controls a size of a focal spot of the optical beam onto the target structure. The optical system maintains an alignment with an optical axis of the system during scanning of the optical beam. The detector system detects a signal beam generated from the target structure during scanning of the optical beam. The signal beam comprises at least a scattered beam generated from the target structure. The processor analyzes the detected signal beam to determine an overlay characteristic of the target structure.

### CROSS-REFERENCE TO RELATED APPLICATIONS

This application claims priority of U.S. application 63/399,966 which was filed on Aug. 22, 2022 and U.S. application 63/512,677 which was filed on Jul. 10, 2023 and which are incorporated herein in their entirety by reference.

### FIELD

The present disclosure relates to a lithographic apparatus. For example, the present disclosure relates to methods and systems for controlling aberrations in lithographic apparatuses and systems.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

During lithographic operation, different processing steps may require different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus may use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters may include, for example, the overlay error between successive layers formed in or on the patterned substrate and critical linewidth of developed photosensitive resist. This measurement can be performed on a product substrate and/or on a dedicated metrology target. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

Such optical scatterometers can be used to measure parameters, such as critical dimensions of developed photosensitive resist or overlay error (OV) between two layers formed in or on the patterned substrate. Properties of the substrate can be determined by comparing the properties of an illumination beam before and after the beam has been reflected or scattered by the substrate.

An overlay system may use four off-axis images to measure the overlay error between the two layers formed in or on the patterned substrate. The overlay system can suffer from optical aberrations that affect the quality of the off-axis images.

### SUMMARY

Accordingly, there is a need to improve the quality of the images in the overlay system. For example it is desirable to control optical aberrations in the overlay system to achieve a better image quality and focus.

In some embodiments, a system includes an illumination system, a scanning system, an optical system, a detector system, and a processor. The illumination system directs an optical beam to illuminate a target structure. The scanning system scans the optical beam and controls a size of a focal spot of the optical beam onto the target structure. The optical system maintains an alignment with an optical axis of the system during scanning of the optical beam. The detector system detects a signal beam generated from the target structure during scanning of the optical beam. The signal beam comprises at least a scattered beam generated from the target structure. The processor analyzes the detected signal beam to determine an overlay characteristic of the target structure.

In some embodiments, a method includes irradiating a target structure with an optical beam, and controlling a focal spot of the optical beam on the target structure. The method also includes directing a signal beam from the scattered beams from the target structure towards a detector system. The signal beam comprises at least a scattered beam generated from the target structure. The method also includes analyzing the signal beam to determine an overlay characteristic of the target structure.

In some embodiments, a lithography apparatus includes an illumination apparatus, a projection system, and a metrology system. The illumination apparatus illuminates a pattern of a patterning device. A projection system projects an image of the pattern onto a substrate. The metrology system includes an illumination system, a scanning system, an optical system, a detector system, and a processor. The illumination system directs an optical beam to illuminate a target structure. The scanning system scans the optical beam and controls a size of a focal spot of the optical beam onto the target structure. The optical system maintains an alignment with an optical axis of the system during scanning of the optical beam. The detector system detects a signal beam generated from the target structure during scanning of the optical beam. The signal beam comprises at least a scattered beam generated from the target structure. The processor analyzes the detected signal beam to determine an overlay characteristic of the target structure.

Further features of the present disclosure, as well as the structure and operation of various embodiments, are described in detail below with reference to the accompanying drawings. It is noted that the present disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable a person skilled in the relevant art(s) to make and use embodiments described herein.

FIG. 1A shows a schematic of a reflective lithographic apparatus, according to some embodiments.

FIG. 1B shows a schematic of a transmissive lithographic apparatus, according to some embodiments.

FIG. 2 shows a more detailed schematic of the reflective lithographic apparatus, according to some embodiments.

FIG. 3 shows a schematic of a lithographic cell, according to some embodiments.

FIGS. 4A and 4B show schematics of inspection apparatuses, according to some embodiments.

FIGS. 5A, 5B, and 5C show schematics of lithographic apparatuses, according to some embodiments.

FIG. 6 shows a schematic of exemplary fields and pupils, according to some embodiments.

FIG. 7 shows a process for performing functions related to correcting aberrations, according to some embodiments.

FIG. 8 shows a schematic of an overlay system, according to some embodiments.

FIG. 9 shows a schematic of an overlay system, according to some embodiments.

FIG. 10 shows a process for performing functions related to determining an overlay characteristic, according to some embodiments.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) are provided as examples. The scope of the present disclosure is not limited to the disclosed embodiment(s). Claimed features are defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

Embodiments of the disclosure can be implemented in hardware, firmware, software, or any combination thereof. Embodiments of the disclosure may also be implemented as instructions stored on a machine-readable medium, which can be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure can be implemented.

### Example Lithographic Systems

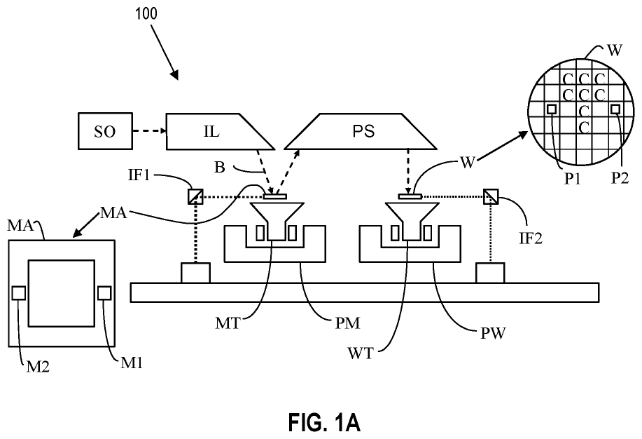

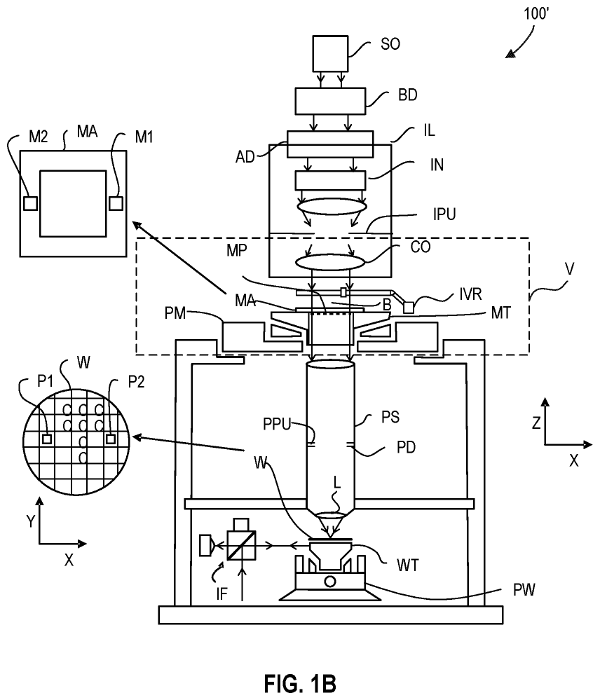

FIGS. 1A and 1B show schematic illustrations of a lithographic apparatus 100 and lithographic apparatus 100′, respectively, in which embodiments of the present disclosure may be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT may use mechanical, vacuum, electrostatic, or other clamping techniques to hold the patterning device MA. The support structure MT may be a frame or a table, for example, which may be fixed or movable, as required. By using sensors, the support structure MT may ensure that the patterning device MA is at a desired position, for example, with respect to the projection system PS.

The term “patterning device” MA should be broadly interpreted as referring to any device that may be used to impart a radiation beam B with a pattern in its cross-section, such as to create a pattern in the target portion C of the substrate W. The pattern imparted to the radiation beam B may correspond to a particular functional layer in a device being created in the target portion C to form an integrated circuit.

The terms “inspection apparatus,” “metrology system,” or the like may be used herein to refer to, e.g., a device or system used for measuring a property of a structure (e.g., overlay error, critical dimension parameters) or used in a lithographic apparatus to inspect an alignment of a wafer (e.g., alignment apparatus).

The patterning device MA may be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which may be individually tilted so as to reflect an incoming radiation beam in different directions. The tilted mirrors impart a pattern in the radiation beam B, which is reflected by a matrix of small mirrors.

The term “projection system” PS may encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment may be used for EUV or electron beam radiation since other gases may absorb too much radiation or electrons. A vacuum environment may therefore be provided to the whole beam path with the aid of a vacuum wall and vacuum pumps.

Lithographic apparatus 100 and/or lithographic apparatus 100′ may be of a type having two (dual stage) or more substrate tables WT (and/or two or more mask tables). In such “multiple stage” machines, the additional substrate tables WT may be used in parallel, or preparatory steps may be carried out on one or more tables while one or more other substrate tables WT are being used for exposure. In some situations, the additional table may not be a substrate table WT.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ may be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO may be an integral part of the lithographic apparatus 100, 100′, for example, when the source SO is a mercury lamp. The source SO and the illuminator IL, together with the beam delivery system BD, if required, may be referred to as a radiation system.

The illuminator IL may include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator may be adjusted. In addition, the illuminator IL may comprise various other components (in FIG. 1B), such as an integrator IN and a condenser CO. The illuminator IL may be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT may be moved accurately (for example, so as to position different target portions C in the path of the radiation beam B). Similarly, the first positioner PM and another position sensor IF1 may be used to accurately position the patterning device (for example, mask) MA with respect to the path of the radiation beam B. Patterning device (for example, mask) MA and substrate W may be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP may include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth order diffracted beams, but also first-order or first- and higher-order diffracted beams (not shown). In some embodiments, dipole illumination for imaging line patterns extending in a direction perpendicular to a line may be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some embodiments, astigmatism aberration may be reduced by providing radiation poles (not shown) in opposite quadrants of the illumination system pupil IPU. Further, in some embodiments, astigmatism aberration may be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT may be moved accurately (for example, so as to position different target portions C in the path of the radiation beam B). Similarly, the first positioner PM and another position sensor (not shown in FIG. 1B) may be used to accurately position the mask MA with respect to the path of the radiation beam B (for example, after mechanical retrieval from a mask library or during a scan).

In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the mask table MT may be connected to a short-stroke actuator only or may be fixed. Mask MA and substrate W may be aligned using mask alignment marks M1, M2, and substrate alignment marks P1, P2. Although the substrate alignment marks (as illustrated) occupy dedicated target portions, they may be located in spaces between target portions (known as scribe-lane alignment marks). Similarly, in situations in which more than one die is provided on the mask MA, the mask alignment marks may be located between the dies.

Mask table MT and patterning device MA may be in a vacuum chamber V, where an in-vacuum robot IVR may be used to move patterning devices such as a mask in and out of vacuum chamber. Alternatively, when mask table MT and patterning device MA are outside of the vacuum chamber, an out-of-vacuum robot may be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ may be used in at least one of the following modes:

1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C may be exposed.

2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT may be determined by the (de-)magnification and image reversal characteristics of the projection system PS.

3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO may be employed and the programmable patterning device is updated as required after each movement of the substrate table WT or in between successive radiation pulses during a scan. This mode of operation may be readily applied to maskless lithography that utilizes a programmable patterning device, such as a programmable mirror array.

Combinations and/or variations on the described modes of use or entirely different modes of use may also be employed.

In a further embodiment, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

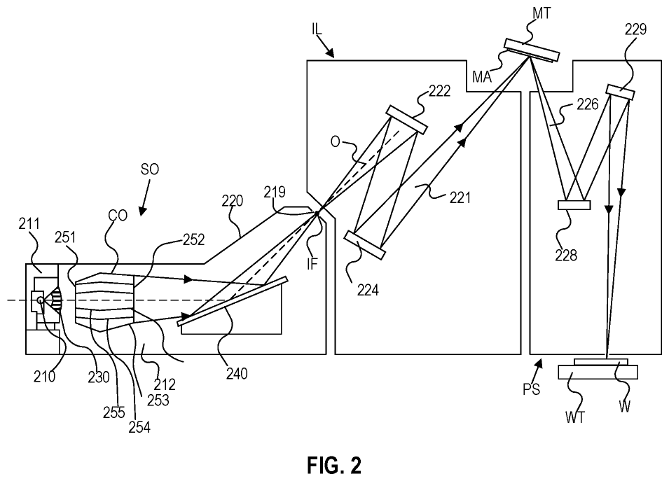

FIG. 2 shows the lithographic apparatus 100 in more detail, including the source collector apparatus SO, the illumination system IL, and the projection system PS. The source collector apparatus SO is constructed and arranged such that a vacuum environment may be maintained in an enclosing structure 220 of the source collector apparatus SO. An EUV radiation emitting plasma 210 may be formed by a discharge produced plasma source. EUV radiation may be produced by a gas or vapor, for example Xe gas, Li vapor, or Sn vapor in which the very hot plasma 210 is created to emit radiation in the EUV range of the electromagnetic spectrum. The very hot plasma 210 is created by, for example, an electrical discharge causing at least a partially ionized plasma. Partial pressures of, for example, 10 Pa of Xe, Li, Sn vapor, or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure.

The collector chamber 212 may include a radiation collector CO, which may be a so-called grazing incidence collector. Radiation collector CO has an upstream radiation collector side 251 and a downstream radiation collector side 252. Radiation that traverses collector CO may be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the radiation emitting plasma 210. Grating spectral filter 240 is used in particular for suppressing infra-red (IR) radiation.

Subsequently the radiation traverses the illumination system IL, which may include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown may generally be present in illumination optics unit IL and projection system PS. The grating spectral filter 240 may optionally be present, depending upon the type of lithographic apparatus. Further, there may be more mirrors present than those shown in the FIG. 2, for example there may be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Exemplary Lithographic Cell

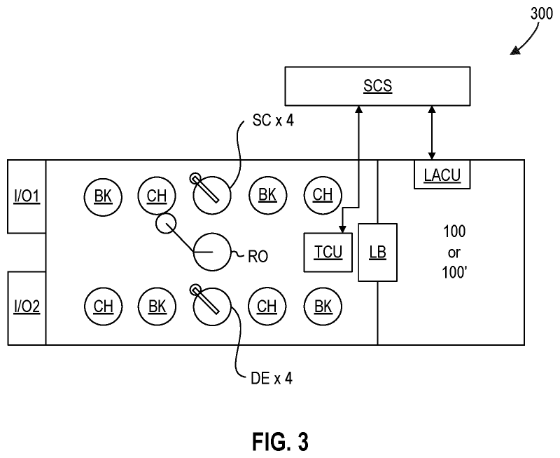

FIG. 3 shows a lithographic cell 300, also sometimes referred to a lithocell or cluster, according to some embodiments. Lithographic apparatus 100 or 100′ may form part of lithographic cell 300. Lithographic cell 300 may also include one or more apparatuses to perform pre- and post-exposure processes on a substrate. In some examples, these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses may be operated to maximize throughput and processing efficiency.

### Exemplary Inspection Apparatus

In order to control the lithographic process to place device features accurately on the substrate, alignment marks are generally provided on the substrate, and the lithographic apparatus includes one or more inspection apparatuses for accurate positioning of marks on a substrate. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.). Generally marks are measured separately to obtain X- and Y-positions. A combined X- and Y-measurement may be performed using the techniques described in U.S. Publication No. 2009/195768 A (Bijnen et al.), however. The full contents of both of these disclosures are incorporated herein by reference.

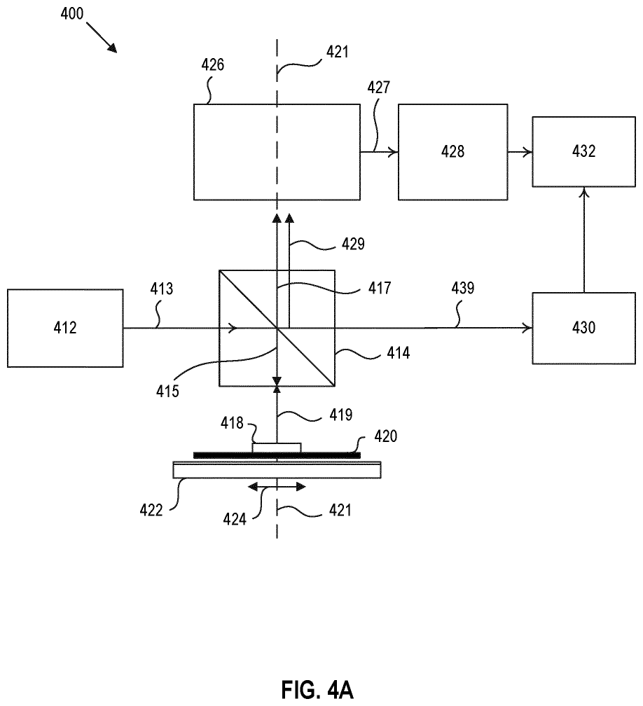

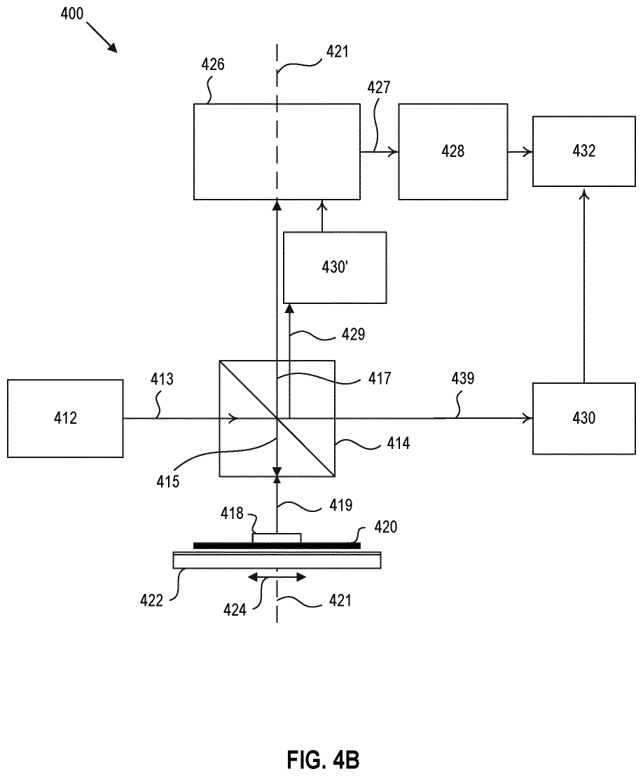

FIG. 4A shows a schematic of a cross-sectional view of an inspection apparatus

400 that may be implemented as a part of lithographic apparatus 100 or 100′, according to some embodiments. In some embodiments, inspection apparatus 400 may be configured to align a substrate (e.g., substrate W) with respect to a patterning device (e.g., patterning device MA). Inspection apparatus 400 may be further configured to detect positions of alignment marks on the substrate and to align the substrate with respect to the patterning device or other components of lithographic apparatus 100 or 100′ using the detected positions of the alignment marks. Such alignment of the substrate may ensure accurate exposure of one or more patterns on the substrate.

In some embodiments, inspection apparatus 400 may include an illumination system 412, a beam splitter 414, an interferometer 426, a detector 428, a beam analyzer 430, and an overlay calculation processor 432. Illumination system 412 may be configured to provide an electromagnetic narrow band radiation beam 413 having one or more passbands. In an example, the one or more passbands may be within a spectrum of wavelengths between about 500 nm to about 900 nm. In another example, the one or more passbands may be discrete narrow passbands within a spectrum of wavelengths between about 500 nm to about 900 nm. Illumination system 412 may be further configured to provide one or more passbands having substantially constant center wavelength (CWL) values over a long period of time (e.g., over a lifetime of illumination system 412). Such configuration of illumination system 412 may help to prevent the shift of the actual CWL values from the desired CWL values, as discussed above, in current alignment systems. And, as a result, the use of constant CWL values may improve long-term stability and accuracy of alignment systems (e.g., inspection apparatus 400) compared to the current alignment apparatuses.

In some embodiments, beam splitter 414 may be configured to receive radiation beam 413 and split radiation beam 413 into at least two radiation sub-beams. For example, radiation beam 413 may be split into radiation sub-beams 415 and 417, as shown in FIG. 4A. Beam splitter 414 may be further configured to direct radiation sub-beam 415 onto a substrate 420 placed on a stage 422. In one example, the stage 422 is movable along direction 424. Radiation sub-beam 415 may be configured to illuminate an alignment mark or a target 418 located on substrate 420. Alignment mark or target 418 may be coated with a radiation sensitive film. In some embodiments, alignment mark or target 418 may have one hundred and eighty degrees (i.e., 180°) symmetry. That is, when alignment mark or target 418 is rotated 180° about an axis of symmetry perpendicular to a plane of alignment mark or target 418, rotated alignment mark or target 418 may be substantially identical to an unrotated alignment mark or target 418. The target 418 on substrate 420 may be (a) a resist layer grating comprising bars that are formed of solid resist lines, or (b) a product layer grating, or (c) a composite grating stack in an overlay target structure comprising a resist grating overlaid or interleaved on a product layer grating. The bars may alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. One in-line method used in device manufacturing for measurements of line width, pitch, and critical dimension makes use of a technique known as “scatterometry”. Methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677 (1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, may be input to the reconstruction process, performed by processing unit PU, from knowledge of the printing step and/or other scatterometry processes.

In some embodiments, beam splitter 414 may be further configured to receive diffraction radiation beam 419 and split diffraction radiation beam 419 into at least two radiation sub-beams, according to an embodiment. Diffraction radiation beam 419 may be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. It would be apparent to a person skilled in the relevant art that other optical arrangements may be used to obtain the similar result of illuminating alignment mark or target 418 on substrate 420 and detecting an image of alignment mark or target 418.

As illustrated in FIG. 4A, interferometer 426 may be configured to receive radiation sub-beam 417 and diffracted radiation sub-beam 429 through beam splitter 414. In an example embodiment, diffracted radiation sub-beam 429 may be at least a portion of radiation sub-beam 415 that may be reflected from alignment mark or target 418. In an example of this embodiment, interferometer 426 comprises any appropriate set of optical-elements, for example, a combination of prisms that may be configured to form two images of alignment mark or target 418 based on the received diffracted radiation sub-beam 429. It should be appreciated that a good quality image need not be formed, but that the features of alignment mark 418 should be resolved. Interferometer 426 may be further configured to rotate one of the two images with respect to the other of the two images 180° and recombine the rotated and unrotated images interferometrically.

In some embodiments, detector 428 may be configured to receive the recombined image via interferometer signal 427 and detect interference as a result of the recombined image when alignment axis 421 of inspection apparatus 400 passes through a center of symmetry (not shown) of alignment mark or target 418. Such interference may be due to alignment mark or target 418 being 180° symmetrical, and the recombined image interfering constructively or destructively, according to an example embodiment. Based on the detected interference, detector 428 may be further configured to determine a position of the center of symmetry of alignment mark or target 418 and consequently, detect a position of substrate 420. According to an example, alignment axis 421 may be aligned with an optical beam perpendicular to substrate 420 and passing through a center of image rotation interferometer 426. Detector 428 may be further configured to estimate the positions of alignment mark or target 418 by implementing sensor characteristics and interacting with wafer mark process variations.

In a further embodiment, detector 428 determines the position of the center of symmetry of alignment mark or target 418 by performing one or more of the following measurements:
1. measuring position variations for various wavelengths (position shift between colors);
2. measuring position variations for various orders (position shift between diffraction orders); and
3. measuring position variations for various polarizations (position shift between polarizations).

This data may, for example, be obtained with any type of alignment sensor, for example a SMASH (SMart Alignment Sensor Hybrid) sensor, as described in U.S. Pat. No. 6,961,116 that employs a self-referencing interferometer with a single detector and four different wavelengths, and extracts the alignment signal in software, or Athena (Advanced Technology using High order ENhancement of Alignment), as described in U.S. Pat. No. 6,297,876, which directs each of seven diffraction orders to a dedicated detector, which are both incorporated by reference herein in their entireties.

In some embodiments, beam analyzer 430 may be configured to receive and determine an optical state of diffracted radiation sub-beam 439. The optical state may be a measure of beam wavelength, polarization, or beam profile. Beam analyzer 430 may be further configured to determine a position of stage 422 and correlate the position of stage 422 with the position of the center of symmetry of alignment mark or target 418. As such, the position of alignment mark or target 418 and, consequently, the position of substrate 420 may be accurately known with reference to stage 422. Alternatively, beam analyzer 430 may be configured to determine a position of inspection apparatus 400 or any other reference element such that the center of symmetry of alignment mark or target 418 may be known with reference to inspection apparatus 400 or any other reference element. Beam analyzer 430 may be a point or an imaging polarimeter with some form of wavelength-band selectivity. In some embodiments, beam analyzer 430 may be directly integrated into inspection apparatus 400, or connected via fiber optics of several types: polarization preserving single mode, multimode, or imaging, according to other embodiments.

In some embodiments, beam analyzer 430 may be further configured to determine the overlay data between two patterns on substrate 420. One of these patterns may be a reference pattern on a reference layer. The other pattern may be an exposed pattern on an exposed layer. The reference layer may be an etched layer already present on substrate 420. The reference layer may be generated by a reference pattern exposed on the substrate by lithographic apparatus 100 and/or 100′. The exposed layer may be a resist layer exposed adjacent to the reference layer. The exposed layer may be generated by an exposure pattern exposed on substrate 420 by lithographic apparatus 100 or 100′. The exposed pattern on substrate 420 may correspond to a movement of substrate 420 by stage 422. In some embodiments, the measured overlay data may also indicate an offset between the reference pattern and the exposure pattern. The measured overlay data may be used as calibration data to calibrate the exposure pattern exposed by lithographic apparatus 100 or 100′, such that after the calibration, the offset between the exposed layer and the reference layer may be minimized.

In some embodiments, beam analyzer 430 may be further configured to determine a model of the product stack profile of substrate 420, and may be configured to measure overlay, critical dimension, and focus of target 418 in a single measurement. The product stack profile contains information on the stacked product such as alignment mark, target 418, or substrate 420, and may include mark process variation-induced optical signature metrology that is a function of illumination variation. The product stack profile may also include product grating profile, mark stack profile, and mark asymmetry information. An example of beam analyzer 430 is Yieldstar™, manufactured by ASML, Veldhoven, The Netherlands, as described in U.S. Pat. No. 8,706,442, which is incorporated by reference herein in its entirety. Beam analyzer 430 may be further configured to process information related to a particular property of an exposed pattern in that layer. For example, beam analyzer 430 may process an overlay parameter (an indication of the positioning accuracy of the layer with respect to a previous layer on the substrate or the positioning accuracy of the first layer with respective to marks on the substrate), a focus parameter, and/or a critical dimension parameter (e.g., line width and its variations) of the depicted image in the layer. Other parameters are image parameters relating to the quality of the depicted image of the exposed pattern.

In some embodiments, an array of detectors (not shown) may be connected to beam analyzer 430, and allows the possibility of accurate stack profile detection as discussed below. For example, detector 428 may be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range but each need separate pre-amps. The number of elements is therefore limited. CCD linear arrays offer many elements that may be read-out at high speed and are especially of interest if phase-stepping detection is used.

In some embodiments, a second beam analyzer 430′ may be configured to receive and determine an optical state of diffracted radiation sub-beam 429, as shown in FIG. 4B. The optical state may be a measure of beam wavelength, polarization, or beam profile. Second beam analyzer 430′ may be identical to beam analyzer 430. Alternatively, second beam analyzer 430′ may be configured to perform at least all the functions of beam analyzer 430, such as determining a position of stage 422 and correlating the position of stage 422 with the position of the center of symmetry of alignment mark or target 418. As such, the position of alignment mark or target 418 and, consequently, the position of substrate 420, may be accurately known with reference to stage 422. Second beam analyzer 430′ may also be configured to determine a position of inspection apparatus 400, or any other reference element, such that the center of symmetry of alignment mark or target 418 may be known with reference to inspection apparatus 400, or any other reference element. Second beam analyzer 430′ may be further configured to determine the overlay data between two patterns and a model of the product stack profile of substrate 420. Second beam analyzer 430′ may also be configured to measure overlay, critical dimension, and focus of target 418 in a single measurement.

In some embodiments, second beam analyzer 430′ may be directly integrated into inspection apparatus 400, or it may be connected via fiber optics of several types: polarization preserving single mode, multimode, or imaging, according to other embodiments. Alternatively, second beam analyzer 430′ and beam analyzer 430 may be combined to form a single analyzer (not shown) configured to receive and determine the optical states of both diffracted radiation sub-beams 429 and 439.

In some embodiments, processor 432 receives information from detector 428 and beam analyzer 430. For example, processor 432 may be an overlay calculation processor. The information may comprise a model of the product stack profile constructed by beam analyzer 430. Alternatively, processor 432 may construct a model of the product mark profile using the received information about the product mark. In either case, processor 432 constructs a model of the stacked product and overlay mark profile using or incorporating a model of the product mark profile. The stack model is then used to determine the overlay offset and minimizes the spectral effect on the overlay offset measurement. Processor 432 may create a basic correction algorithm based on the information received from detector 428 and beam analyzer 430, including but not limited to the optical state of the illumination beam, the alignment signals, associated position estimates, and the optical state in the pupil, image, and additional planes. The pupil plane is the plane in which the radial position of radiation defines the angle of incidence and the angular position defines the azimuth angle of the radiation. Processor 432 may utilize the basic correction algorithm to characterize the inspection apparatus 400 with reference to wafer marks and/or alignment marks 418.

In some embodiments, processor 432 may be further configured to determine printed pattern position offset error with respect to the sensor estimate for each mark based on the information received from detector 428 and beam analyzer 430. The information includes but is not limited to the product stack profile, measurements of overlay, critical dimension, and focus of each alignment marks or target 418 on substrate 420. Processor 432 may utilize a clustering algorithm to group the marks into sets of similar constant offset error, and create an alignment error offset correction table based on the information. The clustering algorithm may be based on overlay measurement, the position estimates, and additional optical stack process information associated with each set of offset errors. The overlay is calculated for a number of different marks, for example, overlay targets having a positive and a negative bias around a programmed overlay offset. The target that measures the smallest overlay is taken as reference (as it is measured with the best accuracy). From this measured small overlay, and the known programmed overlay of its corresponding target, the overlay error may be deduced. Table 1 illustrates how this may be performed. The smallest measured overlay in the example shown is −1 nm. However, this is in relation to a target with a programmed overlay of −30 nm. The process may have introduced an overlay error of 29 nm.

TABLE 1

| | | | | | | | |
|---|---|---|---|---|---|---|---|
| Programmed overlay | −70 | −50 | −30 | −10 | 10 | 30 | 50 |
| Measured overlay | −38 | −19 | −1 | 21 | 43 | 66 | 90 |
| Difference between measured | 32 | 31 | 29 | 31 | 33 | 36 | 40 |
| and programmed overlay | | | | | | | |
| Overlay error | 3 | 2 | — | 2 | 4 | 7 | 11 |

The smallest value may be taken to be the reference point and, relative to this, the offset may be calculated between measured overlay and that expected due to the programmed overlay. This offset determines the overlay error for each mark or the sets of marks with similar offsets. Therefore, in the Table 1 example, the smallest measured overlay was −1 nm, at the target position with programmed overlay of 30 nm. The difference between the expected and measured overlay at the other targets is compared to this reference. A table such as Table 1 may also be obtained from marks and target 418 under different illumination settings, the illumination setting, which results in the smallest overlay error, and its corresponding calibration factor, may be determined and selected. Following this, processor 432 may group marks into sets of similar overlay error. The criteria for grouping marks may be adjusted based on different process controls, for example, different error tolerances for different processes.

In some embodiments, processor 432 may confirm that all or most members of the group have similar offset errors, and apply an individual offset correction from the clustering algorithm to each mark, based on its additional optical stack metrology. Processor 432 may determine corrections for each mark and feed the corrections back to lithographic apparatus 100 or 100′ for correcting errors in the overlay, for example, by feeding corrections into the inspection apparatus 400.

### Example Overlay Systems

In some embodiments, in overlay systems (e.g., wide field overlay systems) four off-axis images are acquired by using four different locations of a pupil space of the overlay system. The four off-axis images may be created using positive first order diffraction signals and negative first order diffraction signals in two directions (i.e., both x and y directions).

In some embodiments, optical aberrations in the overlay system may decrease the quality of the four-axis images and may lead to errors during overlay measurements. Exemplary aspects provide aberration correction in a partially coherent regime. Overlay systems described herein may use adaptive optical technology to control optical aberrations (e.g., wavelength and polarization dependent optical aberrations). Further, the overlay systems described herein may correct optical aberrations per quadrant of the pupil space (e.g., normal and complimentary images). Each quadrant-based-optical image may show different imaging qualities due to both isoplanatic and non-isoplanatic optical aberrations. For large target, the metrology system may behave more non-isoplanatically and the overlay error may increase. The overlay system described herein correct non-isoplanatism as well as isoplanatism in the system that in turn increase the imaging quality for all quadrant-based-optical images, respectively.

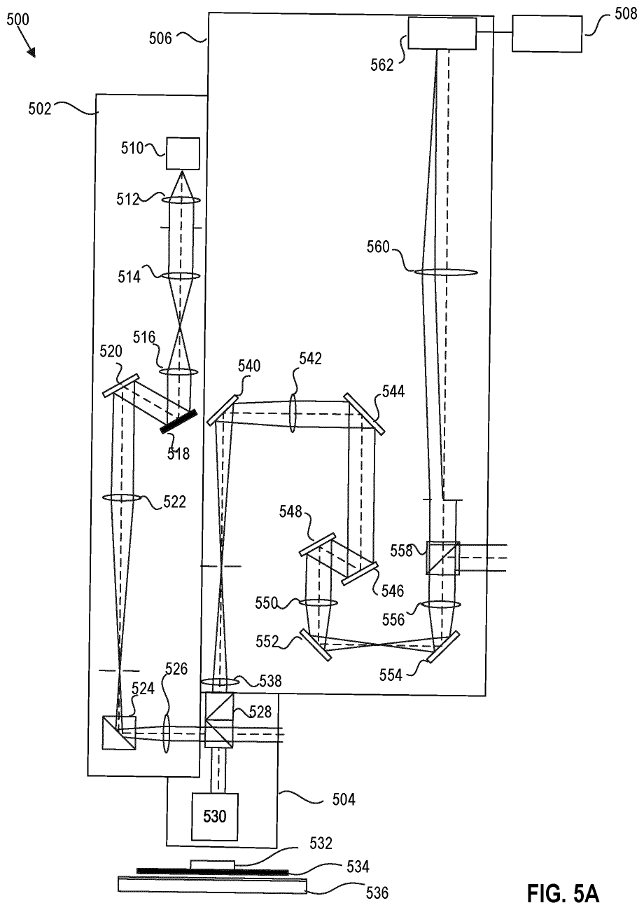

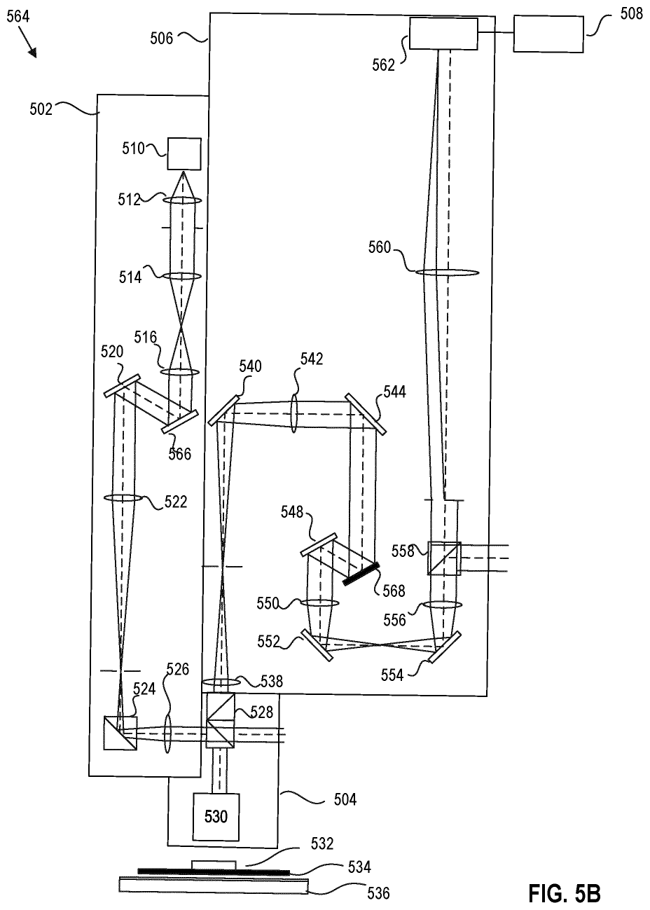

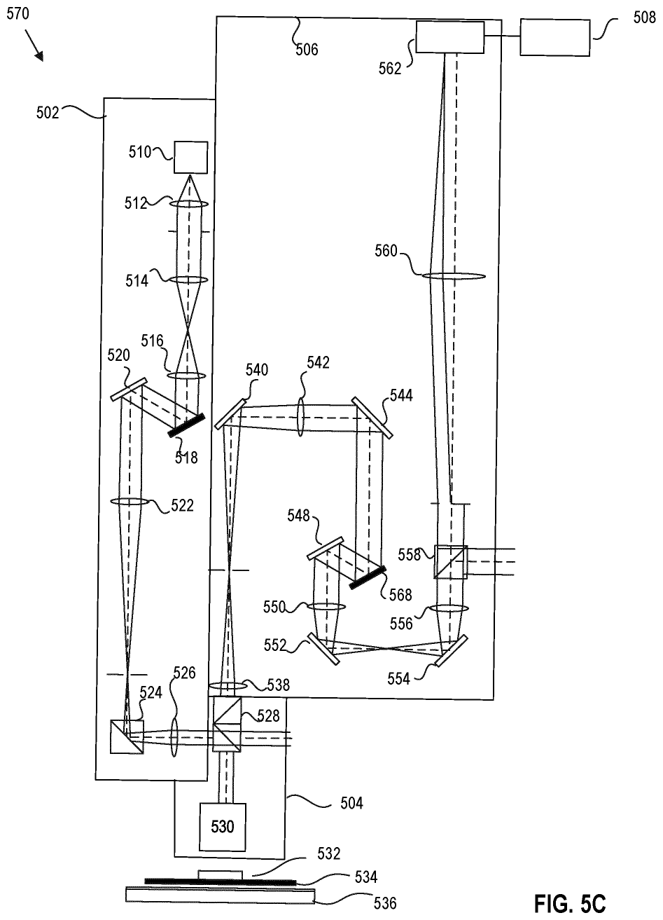

FIG. 5A shows a schematic of an overlay system 500, according to some embodiments. In some embodiments, system 500 may also represent a more detailed view of beam analyzer 430. In some embodiments, system 500 comprises an illumination system 502, an optical system 504, a detector system 506, and a processor 508.

In some embodiments, illumination system 502 may comprise a radiation source 510, optical elements 512, 514, 516 (e.g., a lens or lens system), an optical element 518, a reflective element (e.g., fold mirror) 520, an optical element 522 (e.g., a lens or lens system), a beamsplitter 524, and an optical element 526 (e.g., a lens or lens system). Radiation source 510 is configured to generate an optical beam to illuminate a target 532. Optical element 518 is configured to control (e.g., correct) optical aberrations in system 500. In some embodiments, optical element 518 may be an aberration corrective device such as a deformable mirror (DM), a spatial light modulator (SLM), or an aberration corrector plate (or mask). Optical element 518 may adjust an intensity and/or a phase profile of the optical beam.

In some embodiments, optical element 518 may be positioned in an optical path of the illumination beam before optical system 504. In some aspects, optical element 518 may be positioned at a position where a beam diameter of the optical beam is suitable for aberration correction. For example, optical element 518 may be positioned at a pupil conjugate plane. The pupil conjugate plane may refer to one of the image planes of the pupil plane of system 500. In some aspects, optical element 518 may be positioned slightly off the pupil conjugate plane or at a field plane location.

In some embodiments, illumination system 502 may comprise a spot size selector (not shown). The spot size selector may be positioned after radiation source 510. The spot size selector may be configured to select a spot of size of the illumination beam. In addition, the illumination system 502 may comprise an illumination model selector (IMS) (not shown). The IMS may be positioned after the spot size selector. The IMS may be configured to select a pupil shape from various pupil shapes. Thus, illumination system 502 may illuminate target 532 with various spot sizes and various pupil shapes.

In some embodiments, optical element 518 may control aberrations in images created by two opposite illumination quadrants (sometimes referred to as BMW pupil) of the IMS.

In some aspects, the aberration correction by optical element 518 includes one or more of the following: (1) remove (or substantially reduce) the axial color over the entire illumination path (branch), (2) remove (or substantially reduce) the lateral color over the entire illumination path (branch), (3) remove (or substantially reduce) the sphero-chromatism over the entire illumination path, (4) remove (or substantially reduce) the on-axis coma over the entire illumination path (5) remove (or substantially reduce) the on-axis astigmatism over the entire illumination path, (6) remove (or substantially reduce) the on-axis Petzval over the entire illumination path, and (7) remove (or substantially reduce) the on-axis distortion over the entire illumination path.

In some embodiments, optical system 504 may comprise a reflective element 528 and an optical element 530 (e.g., an objective lens). Reflective element 528 may direct a portion of the optical beam to optical element 530. Optical element 530 may direct the portion of optical beam towards target 532.

FIG. 5A shows a non-limiting depiction of system 500 inspecting target 532 (also referred to as “target structure”) on a substrate 534. The substrate 534 is disposed on a stage 536 that is adjustable (e.g., a support structure that can move). It should be appreciated the structures drawn within illumination system 502 and optical system 504 are not limited to their depicted positions. The positions of structures can vary as necessary, for example, as designed for a modular assembly.

In some embodiments, target 532 can comprise a diffractive structure (e.g., a grating(s)). Target 532 can reflect, refract, diffract, scatter, or the like, radiation. For ease of discussion, and without limitation, radiation that interacts with a target will be termed scattered radiation throughout. The scattered radiation is collected by optical element 530. The scattered radiation comprises the reflection of the illumination beam (zero order) and a first diffraction order beam and a second diffraction order beam (e.g., positive and negative first order diffraction beams, positive and negative second order diffraction beams). For example, the scattered radiation may comprise ±first diffraction orders.

In some embodiments, detection system 506 may comprise an optical element 538, a reflective element (e.g., fold mirror) 540, an optical element 542 (e.g., a lens or lens system), a reflective element (e.g., a mirror) 544, a reflective element (e.g., a mirror) 546, a reflective element (e.g., a mirror) 548, an optical element (e.g., a lens or lens system) 550, a reflective element (e.g., a mirror) 552, a reflective element (e.g., a mirror) 554, an optical element (e.g., a lens or lens system) 556, a beamsplitter 558, an optical element (e.g., a lens or lens system) 560, and an imaging device 562. Beamsplitter 558 may direct a portion of the scattered radiation towards optical element 560. Optical element 560 may be configured to focus the scattered radiation into imaging device 562. Imaging device 562 may be coupled with processor 508. Imaging device 562 may form a two-dimensional image of target 532. Processor 508 may analyze the two-dimensional image to determine an overlay error.

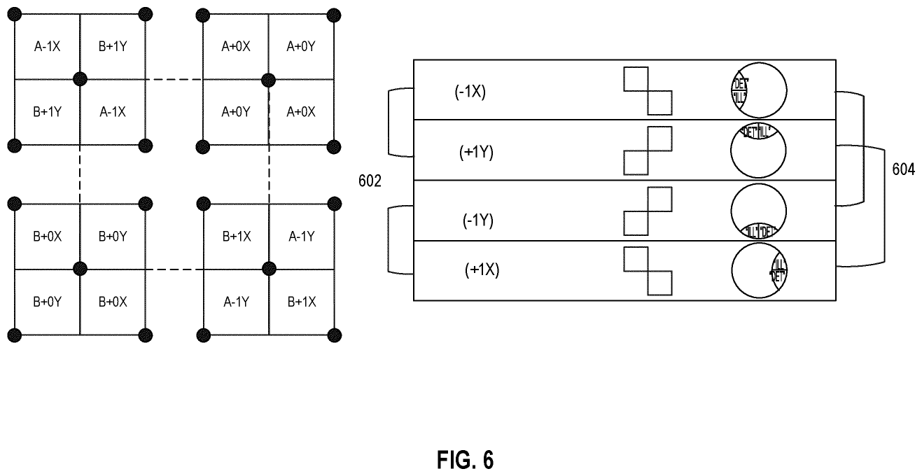

In some embodiments, detection system 506 may measure the overlay error in both x and y directions, simultaneously. For example, imaging device 562 may capture normal and complementary images in the x and y directions as shown in FIG. 6.

In some aspects, due to the color-dependent defocus correction, optical element 518 may introduce the axial color correction so that the illumination path may not need additional axial correction by optical element 530 (i.e., by z repositioning of optical element 530). Optical element 530 may be used for beam focusing onto substrate 534.

In some aspects, optical element 518 may introduce a wavefront tilt in the optical beam. Thus, optical elements 522 and 524 may not use a x and/or a y decentering compensator.

In some aspects, system 500 may include a closed-loop or sensor-less optical aberration control system. For example, system 500 may include a wavefront sensor. The wavefront sensor (not shown) can be configured to provide a feedback to optical element 518. For example, the wavefront sensor may be configured to measure aberrations of an optical wavefront of the optical beam. Optical element 518 such as a deformable mirror may be controlled based on the measured aberrations. In some aspects, processor 508 may receive input from the wavefront sensor. Processor 508 may determine settings for optical element 518 to correct for the aberrations. For example, processor 508 may determine an optimal shape for the surface of the deformable mirror.

In some aspects, the optical element to correct optical aberrations in the overlay system may be positioned in the detection path, as shown in FIG. 5B.

FIG. 5B shows a schematic of an overlay system 564, according to some embodiments. In some embodiments, system 564 may also represent a more detailed view of beam analyzer 430. In some embodiments, system 564 comprises an illumination system 502, an optical system 504, a detector system 506, and a processor 508.

In some embodiments, illumination system 502 may comprise a radiation source 510, optical elements 512, 514, 516 (e.g., a lens or lens system), a reflective element (e.g., mirror) 566, a reflective element (e.g., fold mirror) 520, an optical element 522 (e.g., a lens or lens system), a beamsplitter 524, and an optical element 526 (e.g., a lens or lens system). Radiation source 510 is configured to generate an optical beam to illuminate a target 532.

In some embodiments, illumination system 502 may comprise a spot size selector (not shown). The spot size selector may be positioned after radiation source 510. The spot size selector may be configured to select a spot of size of the illumination beam. In addition, the illumination system 502 may comprise an illumination model selector (IMS) (not shown). The IMS may be positioned after the spot size selector. The IMS may be configured to select a pupil shape from various pupil shapes. Thus, illumination system 502 may illuminate target 532 with various spot sizes and various pupil shapes.

In some embodiments, optical system 504 may comprise a reflective element 528 and an optical element 530 (e.g., an objective lens). Reflective element 528 may direct a portion of the optical beam to optical element 530. Optical element 530 may direct the portion of optical beam towards target 532.

FIG. 5B shows a non-limiting depiction of system 564 inspecting target 532 (also referred to as “target structure”) on a substrate 534. The substrate 534 is disposed on a stage 536 that is adjustable (e.g., a support structure that can move). It should be appreciated the structures drawn within illumination system 502 and optical system 504 are not limited to their depicted positions. The positions of structures can vary as necessary, for example, as designed for a modular assembly.

In some embodiments, target 532 can comprise a diffractive structure (e.g., a grating(s)). Target 532 can reflect, refract, diffract, scatter, or the like, radiation. For ease of discussion, and without limitation, radiation that interacts with a target will be termed scattered radiation throughout. The scattered radiation is collected by optical element 530. The scattered radiation comprises the reflection of the illumination beam and, a first diffraction order beam and a second diffraction order beam. For example, the scattered radiation may comprise ±first diffraction orders.

In some embodiments, detection system 506 may comprise an optical element 538, a reflective element (e.g., fold mirror) 540, an optical element 542 (e.g., a lens or lens system), a reflective element (e.g., a mirror) 544, an optical element 568, a reflective element (e.g., a mirror) 548, an optical element (e.g., a lens or lens system) 550, a reflective element (e.g., a mirror) 552, a reflective element (e.g., a mirror) 554, an optical element (e.g., a lens or lens system) 556, a beamsplitter 558, an optical element (e.g., a lens or lens system) 560, and an imaging device 562. Beamsplitter 558 may direct a portion of the scattered radiation towards optical element 560. Optical element 560 may be configured to focus the scattered radiation into imaging device 562. Imaging device 562 may be coupled with processor 508. Imaging device 562 may form a two-dimensional image of target 532. Processor 508 may analyze the two-dimensional image to determine an overlay error.

Optical element 568 is configured to control (e.g., correct) optical aberrations in system 564. In some embodiments, optical element 568 may be an aberration corrective device such as a deformable mirror (DM), a spatial light modulator (SLM), or an aberration corrector plate (or mask). Optical element 568 may adjust an intensity and/or a phase profile of the scattered radiation.

In some embodiments, optical element 568 may be positioned in an optical path of the scattered radiation collected by optical element 530 after optical system 504. In some aspects, optical element 568 may be positioned at a position where a beam diameter of the optical beam is suitable for aberration correction. For example, optical element 568 may be positioned at a pupil conjugate plane. The pupil conjugate plane may refer to one of the image planes of the pupil plane of system 564. In some aspects, optical element 568 may be positioned slightly off the pupil conjugate plane or at a field plane location.

In some aspects, the aberration correction by optical element 568 includes one or more of the following: (1) remove (or substantially reduce) the axial color over the detection path (branch), (2) remove (or substantially reduce) the lateral color over the entire detection path (branch), (3) remove (or substantially reduce) the sphero-chromatism over the detection path, (4) remove (or substantially reduce) the on-axis coma over the detection path (5) remove (or substantially reduce) the on-axis astigmatism over the detection path, (6) remove (or substantially reduce) the on-axis Petzval over the detection path, and (7) remove (or substantially reduce) the on-axis distortion over detection path.

In some aspects, due to the color-dependent defocus correction, optical element 568 may introduce the axial color correction so that the detection path may not need additional axial correction by optical element 530 (i.e., by z repositioning of optical element 530). Optical element 530 may be used for beam focusing onto substrate 534.

In some embodiments, optical element 568 may control aberrations in images created by each quadrant of a detection wedge pupil in the detection path.

In some aspects, system 564 may include a wavefront sensor. The wavefront sensor (not shown) can be configured to provide a feedback to optical element 568. For example, the wavefront sensor may be configured to measure aberrations of an optical wavefront of the scattered radiations (e.g., first order diffraction beams). Optical element 568 such as a deformable mirror may be controlled based on the measured aberrations. In some aspects, processor 508 may receive input from the wavefront sensor. Processor 508 may determine settings for optical element 508 to correct for the aberrations. For example, processor 508 may determine an optimal shape for the surface of the deformable mirror.

In some embodiments, the overlay system may comprise two or more optical elements configured to correct optical aberrations. For example, a first optical element configured to correct optical aberrations may be positioned in the illumination path and a second optical element configured to correct optical aberrations may be positioned in the detection path as shown in FIG. 5C.

FIG. 5C shows a schematic of an overlay system 570, according to some embodiments. In overlay system 570, optical element 518 may be positioned in the illumination path and optical element 568 may be positioned in the detection path. Elements of FIG. 5C have similar structures and functions as similarly numbered elements in FIG. 5A and FIG. 5B. The description of those elements is omitted for brevity.

In some aspects, system 570 may include a wavefront sensor (not shown). The wavefront sensor can be configured to provide a feedback to optical element 518 and to optical element 568. For example, the wavefront sensor may be configured to measure aberrations of an optical wavefront of the scattered radiations (e.g., first order diffraction beams) (in the detection path) and the optical beam of radiation source 510 (in the illumination path). Optical element 568 and optical element 518 (e.g., deformable mirror or spatial light modulator) may be controlled based on the measured aberrations in the illumination path and/or in the detection path. In some aspects, processor 508 may receive input from the wavefront sensor. Processor 508 may determine settings for optical element 568 and optical element 518 to correct for the aberrations. For example, processor 508 may determine an optimal shape for the surface of the deformable mirror.

FIG. 6 shows a schematic of exemplary fields and pupils, according to some embodiments.

The normal images comprises A−1X and B+1Y. A−1X corresponds to an image of the negative first diffraction order in the x-direction created by the illumination pupil A at IMS. B+1Y corresponds to the image of the positive first diffraction order in the y-direction created by the illumination pupil B. The complementary images comprises B+1X and A−1Y. B+1X corresponds to the image created by the illumination pupil B of the positive first diffraction order in the x-direction. A−1Y corresponds to the image created by the illumination pupil A of the negative first diffraction order in the y-direction.

In some embodiments, optical element 530 may be rotated to control the behavior of differential focus offset between normal and complementary images. This is described in more details in provisional application U.S. Prov. Appl. 63/302,214, entitled METHOD AND APPARATUS FOR ILLUMINATION ADJUSTMENT, the contents of which are incorporated by reference in its entirety. The rotation may not lead to offset coma as the optical aberrations are corrected in both pupils simultaneously.

For example, when the optical element is positioned in the illumination path the optical aberrations for both illumination pupils (i.e., pupil A and pupil B) can be corrected (labelled 604 in FIG. 6). When the optical element is positioned in the detection path, the aberrations for both detection pupils (i.e., pupils A−1X/B+1Y and pupils B+1X/A−1Y) are corrected (labelled 602 in FIG. 6). Thus, optical aberrations for the eight images from target 532 are controlled, individually (i.e., x-image vs. y-image and/or the positive first order image vs the negative first order image).

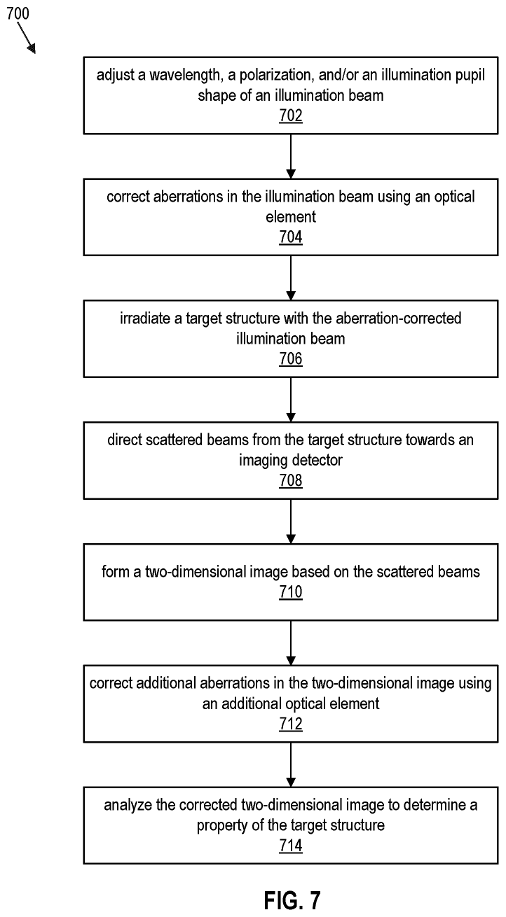

FIG. 7 shows method steps (e.g., using one or more processors) for performing a method 700 including functions described herein, according to some embodiments. The method 700 of FIG. 7 can be performed in any conceivable order and it is not required that all steps be performed. Moreover, the method steps of FIG. 7 described above merely reflect an example of steps and are not limiting.

Method 700 illustrates a method for correcting aberrations. Method 700 includes adjusting a wavelength, a polarization, and/or an illumination pupil shape of the illumination beam, as illustrated in step 702.

The method also includes, correcting optical aberrations (such as wavelength-, polarization-dependent optical aberrations) using an optical element located along the illumination path as illustrated in step 704.

The method also includes irradiating a target structure with the aberration-corrected illumination beam by loading calibration information processed in step 704, as illustrated in step 706.

The method also includes directing scattered beams from the target structure towards an imaging detector, as illustrated in step 708. In some aspects, the scattered beams comprise a first diffraction order beam and a second diffraction order beam (e.g., a negative first diffraction order beam and a positive first diffraction order beam).

The method also includes forming, by the imaging detector, a two-dimensional image based on the scattered beams, as illustrated in step 710.

The method also includes correcting additional aberrations in the two-dimensional image using an additional optical element located along the detection path, as illustrated in step 712. In some aspects, the optical element is positioned at a conjugate plane of a pupil of the imaging detector. In some aspects, the additional aberrations may be caused by any interaction between the illumination beam and target configurations, detection optics only, and/or dynamic imaging environment (i.e., temperature, atmospheric pressure, turbulence).

The method also includes analyzing the corrected two-dimensional image to determine a property of the target structure, as illustrated in step 714.

In some embodiments, in overlay systems an IMS may be used to vary the size of the pupil. The variations in the pupil size may lead to changes in the spatial coherence of the system that decreases the quality of the overlay measurements. For example, the spatial coherence at a detector of the overlay system is a function of wavelength and polarization of the illumination beam, the IMS aperture size, and the wavelength to pitch ratio. The spatial coherence can result in a coherent effect in the overlay measurements that decreases the quality of the measurements. The overlay system described herein is not affected by the wavelength and polarization of the illumination beam.

In some embodiments, a target structure that is used in overlay systems may include four different grating pairs that are proximate to each other's (e.g., micro diffraction based overlay metrology target). The proximity of the gratings may cause unavoidable intra-target intensity cross-talk. In addition, the proximity of neighboring diffractive structure around the target structure causes the case-by-case external intensity cross-talk. Cross-talks leads to overlay measurement errors. Cross-talks in the overlay systems described herein are reduced or eliminated. Thus, the overlay measurement errors are decreased.

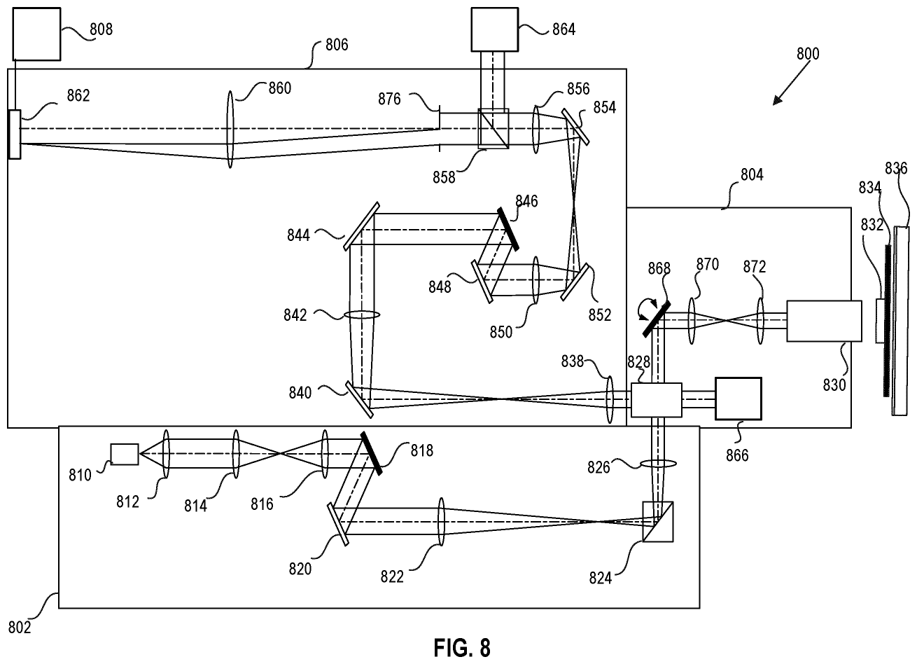

FIG. 8 shows a schematic of an overlay system 800, according to some embodiments. In some embodiments, system 800 may also represent a more detailed view of beam analyzer 430. In some embodiments, system 800 comprises an illumination system 802, an optical system 804, a detector system 806, and a processor 808.

In some embodiments, illumination system 802 may comprise a radiation source 810, optical elements 812, 814, 816 (e.g., a lens or lens system), an optical element 818, a reflective element (e.g., fold mirror) 820, an optical element 822 (e.g., a lens or lens system), a beamsplitter 824, and an optical element 826 (e.g., a lens or lens system). Radiation source 810 is configured to generate an optical beam to illuminate a target 832.

In some embodiments, radiation source 810 may be a spatially coherent light source. Radiation source 810 may have a low “etendue.” In some embodiments, the term “etendue” may be used herein to refer to a property of light of an optical system that characterizes a spread of illumination intensity based on direction of propagation and spatial distribution (e.g., solid angle with respect to a point of origin.) In some embodiments, radiation source 810 is coupled to a single mode fiber. An output from the single mode fiber is imaged using optical element 812. That is, the point source is imaged into target 832. The point source is scanned on target 832 and a confocal image of target 832 may be obtained. Because a point source is used as the illumination source for overlay system 800, the IMS pupil is fixed. Thus, the aberrations are uniform and may be controlled. Optical element 818 may control wavelength and polarization dependent field-constant aberration.

In some embodiments, optical element 818 is configured to control (e.g., correct) optical aberrations in system 800. In some embodiments, optical element 818 may be an aberration corrective device such as a deformable mirror (DM), a spatial light modulator (SLM), or an aberration corrector plate (or mask). Optical element 818 may adjust an intensity and/or a phase profile of the optical beam.

In some embodiments, optical element 818 may be positioned in an optical path of the illumination beam before optical system 804. In some aspects, optical element 818 may be positioned at a position where a beam diameter of the optical beam is suitable for aberration correction. For example, optical element 818 may be positioned at a pupil conjugate plane. The pupil conjugate plane may refer to one of the image planes of the pupil plane of system 800. In some aspects, optical element 818 may be positioned slightly off the pupil conjugate plane or at a field plane location.

In some aspects, the aberration correction by optical element 818 includes one or more of the following: (1) remove (or substantially reduce) the defocus aberration over the entire illumination path (branch), (2) remove (or substantially reduce) the tilt aberration over the entire illumination path (branch), (3) remove (or substantially reduce) the spherical aberration over the entire illumination path, (4) remove (or substantially reduce) the offset coma over the entire illumination path (5) remove (or substantially reduce) the offset astigmatism over the entire illumination path, (6) remove (or substantially reduce) the offset Petzval over the entire illumination path, and (7) remove (or substantially reduce) the offset distortion over the entire illumination path.

In some aspects, optical element 818 may control the focus or defocus of the optical beam (focal spot) into target 832. For example, target 832 may not be moved along the z-direction to focus or defocus the optical beam instead optical element 818 may control the focal spot of the illumination beam.

In some embodiments, optical element 818 may be a reflective element (e.g., a mirror). In some embodiments, optical element 818 may not provide optical aberrations functions.

In some embodiments, optical system 804 may comprise a beamsplitter system 828 (e.g., one or more beamsplitters). Beamsplitter 828 may direct a first portion of the optical beam to a scanning system 868. Beamsplitter 828 may direct a second portion of the optical beam towards a wavefront sensor 866. In some aspects, beamsplitter system 828 directs the full optical beam towards scanning system 868.

In some embodiments, scanning system 868 is configured to scan the optical beam in a first direction and a second direction. This serves to scan target 832 in the first direction and the second direction. In some aspects, scanning system 868 may be a MEMS mirror. In some aspects, scanning system 868 may comprise one or more galvo-mirrors. In some aspects, a two-dimensional MEMS mirror having a tilt angle of ±5 mrad may be used. By controlling the angle of the MEMS mirror, the illuminated area on target 832 is changed. For example, the MEMS mirror may be controlled to move the optical beam in a predefined scanning pattern over target 832. A relay system may relay the optical beam towards optical element 830. Optical element 830 may direct the portion of optical beam towards target 832. Relay system may comprise a first optical element 870 (e.g., a lens or lens system) and a second optical element 872 (e.g., a lens or lens system).

FIG. 8 shows a non-limiting depiction of system 800 inspecting target 832 (also referred to as “target structure”) on a substrate 834. The substrate 834 is disposed on a stage 836 that is adjustable (e.g., a support structure that can move). It should be appreciated the structures drawn within illumination system 802 and optical system 804 are not limited to their depicted positions. The positions of structures can vary as necessary, for example, as designed for a modular assembly.

In some embodiments, target 832 can comprise a diffractive structure (e.g., a grating(s)). Target 832 can reflect, refract, diffract, scatter, or the like, radiation. For ease of discussion, and without limitation, radiation that interacts with a target will be termed scattered radiation throughout. The scattered radiation is collected by optical element 830. The scattered radiation comprises the reflection of the illumination beam (zero order) and a first diffraction order beam and a second diffraction order beam (e.g., positive and negative first order diffraction beams, positive and negative second order diffraction beams). For example, the scattered radiation may comprise ±first diffraction orders.

In some embodiments, detection system 806 may comprise an optical element 838, a reflective element (e.g., fold mirror) 840, an optical element 842 (e.g., a lens or lens system), a reflective element (e.g., a mirror) 844, an optical element 846, a reflective element (e.g., a mirror) 848, an optical element (e.g., a lens or lens system) 850, a reflective element (e.g., a mirror) 852, a reflective element (e.g., a mirror) 854, an optical element (e.g., a lens or lens system) 856, a beamsplitter 858, an optical element 876 (e.g., wedge), an optical element (e.g., a lens or lens system) 860, and a detector 862 (e.g., a photodetector). Beamsplitter 858 may direct a portion of the scattered radiation towards optical element 860. Beamsplitter 858 may direct another portion of the scattered radiation towards a wavefront sensor 864. Optical element 860 may be configured to focus the scattered radiation into detector 862. Detector 862 may be coupled with processor 808. Detector 862 may generate a signal beam as a function of the scattered direction. Processor 808 may form a two-dimensional image of target 832. Processor 808 may analyze the two-dimensional image to determine an overlay error.

Optical element 846 is configured to control (e.g., correct) optical aberrations in system 800. In some embodiments, optical element 846 may be an aberration corrective device such as a deformable mirror (DM), a spatial light modulator (SLM), or an aberration corrector plate (or mask). Optical element 846 may adjust an intensity and/or a phase profile of the scattered radiation.

In some embodiments, optical element 846 may be positioned in an optical path of the scattered radiation collected by optical element 830 after optical system 804. In some aspects, optical element 846 may be positioned at a position where a beam diameter of the optical beam is suitable for aberration correction. For example, optical element 846 may be positioned at a pupil conjugate plane. The pupil conjugate plane may refer to one of the image planes of the pupil plane of system 800. In some aspects, optical element 846 may be positioned slightly off the pupil conjugate plane or at a field plane location. In some aspects, optical element 846 may correct for optical aberrations introduced from target misalignment and inaccuracies in the z-direction.

In some aspects, the aberration correction by optical element 846 includes one or more of the following: (1) remove (or substantially reduce) the defocus aberration over the entire illumination path (branch), (2) remove (or substantially reduce) the tilt aberration over the entire illumination path (branch), (3) remove (or substantially reduce) the spherical aberration over the entire illumination path, (4) remove (or substantially reduce) the offset coma over the entire illumination path (5) remove (or substantially reduce) the offset astigmatism over the entire illumination path, (6) remove (or substantially reduce) the offset Petzval over the entire illumination path, and (7) remove (or substantially reduce) the offset distortion over the entire illumination path.

In some embodiments, optical element 846 may be a reflective element (e.g., a mirror). In this case optical element 846 may not be configured to control optical aberrations in system 800.

In some aspects, system 800 may include a closed-loop or sensor-less optical aberration control system. In some aspects, system 800 may include wavefront sensor 866 (e.g., Shack Hartmann sensor) and wavefront sensor 864 (e.g., Shack Hartmann sensor). Wavefront sensor 866 can be configured to provide a feedback to optical element 818. For example, wavefront sensor 866 may be configured to measure aberrations of an optical wavefront of the optical beam. Optical element 818 such as a deformable mirror may be controlled based on the measured aberrations (e.g., varying a control signal of the deformable mirror). In some aspects, processor 808 may receive input from wavefront sensor 866. Processor 808 may determine settings for optical element 818 to correct for the aberrations. For example, processor 808 may determine an optimal shape for the surface of the deformable mirror.

In some aspects, wavefront sensor 864 can be configured to provide a feedback to optical element 846. For example, wavefront sensor 864 may be configured to measure aberrations of an optical wavefront of the scattered beam. Optical element 846 such as a deformable mirror may be controlled based on the measured aberrations (e.g., varying a control signal of the deformable mirror). In some aspects, processor 808 may receive input from wavefront sensor 864. Processor 808 may determine settings for optical element 846 to correct for the aberrations. For example, processor 808 may determine an optimal shape for the surface of the deformable mirror.

In some embodiments, the field of view of system 800 is small compared to an overlay system having a different illumination source (i.e., not a point source). Only an area of interest of target 832 is illuminated at a position of the scanning system. Thus, cross-talk from other features is minimized.

In some embodiments, a size of the illumination of the optical beam may be controlled, thus overfill or underfill conditions with respect to target 832 may be achieved. Overfill may refer to illuminating more than a desired target area. Underfill may refer to illuminating less than the desired target area. For example, if scattering from the background (i.e., areas proximate to the desired target area) is detected by detection system 806, then the field of view may be decreased. In some aspects, if scattering from the background is not detected, then the field of view may be increased during the scanning.

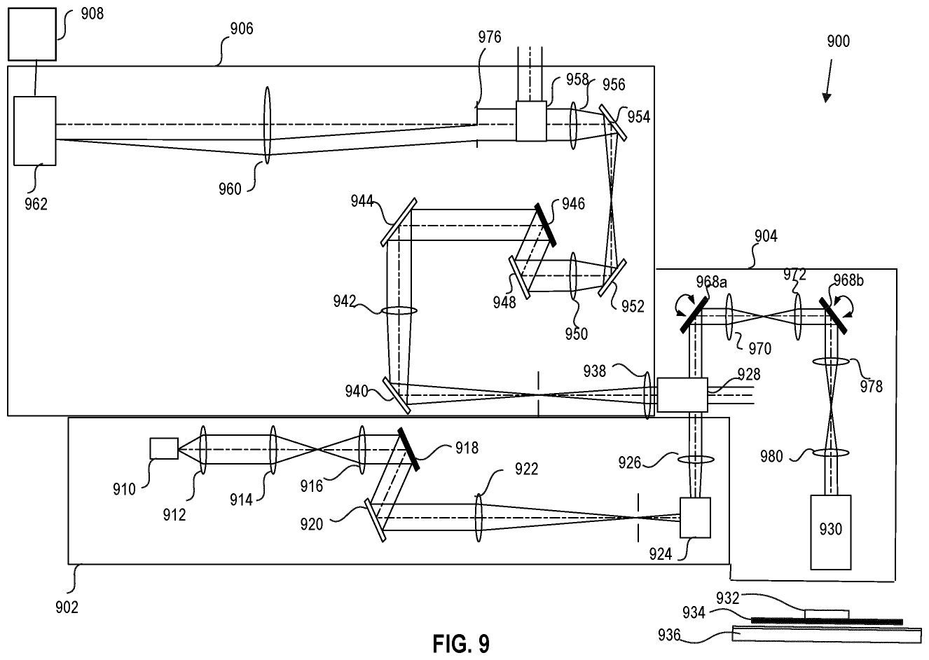

FIG. 9 shows a schematic of an overlay system 900, according to some embodiments. In some embodiments, system 900 may also represent a more detailed view of beam analyzer 430. Elements of FIG. 9 have similar structures and functions as similarly numbered elements (last two digits) in FIG. 8. The description of those elements is omitted for brevity.

In some embodiments, system 900 comprises an illumination system 902, an optical system 904, a detector system 906, and a processor 908.

In some embodiments, illumination system 902 may comprise a radiation source 910, optical elements 912, 914, 916 (e.g., a lens or lens system), an optical element 918, a reflective element (e.g., fold mirror) 920, an optical element 922 (e.g., a lens or lens system), a beamsplitter 924, and an optical element 926 (e.g., a lens or lens system). Radiation source 910 is configured to generate an optical beam to illuminate a target 932.

In some embodiments, radiation source 910, optical element 918, and optical element 946 may have similar structure and function as radiation source 810, optical element 818, and optical element 846, respectively. The detailed description of those elements is omitted for brevity.

In some embodiments, optical system 904 may comprise a beamsplitter system 928 (e.g., one or more beamsplitters). Beamsplitter 928 may direct a first portion of the optical beam to a scanning system. Beamsplitter 928 may direct a second portion of the optical beam towards a wavefront sensor (not shown). In some aspects, beamsplitter system 928 directs the whole optical beam towards scanning system.

In some embodiments, scanning system is configured to scan the optical beam in a first direction and a second direction. In some aspects, scanning system may comprise a first scanning device 968a and a second scanning device 968b. This serves to scan target 932 in the first direction and the second direction. In some aspects, first scanning device 968a may be a first MEMS mirror and second scanning device 968b may be a second MEMS device. By controlling the angle of the MEMS mirror, the illuminated area on target 932 is changed. For example, first scanning device 968a may be controlled to move the optical beam in a first dimension (e.g., along x direction) over target 932 at a first speed. Second scanning device 968b may be controlled to move the optical beam in a second direction (e.g., along y direction) at a second speed. In some aspects, the first speed may be greater than the second speed. Having two scanning devices may increase the detection speed of system 900.

A relay system may relay the optical beam towards optical element 930. Optical element 930 may direct the portion of or the full optical beam towards target 932. Relay system may comprise a first optical element 970 (e.g., a lens or lens system) and a second optical element 972 (e.g., a lens or lens system). A second relay may be positioned after scanning device 968b. Second relay may comprise a first optical element 978 (e.g., a lens or a lens system) and a second optical element 980 (e.g., a lens or a lens system).

FIG. 9 shows a non-limiting depiction of system 900 inspecting target 932 (also referred to as “target structure”) on a substrate 934. The substrate 934 is disposed on a stage 936 that is adjustable (e.g., a support structure that can move). It should be appreciated the structures drawn within illumination system 902 and optical system 904 are not limited to their depicted positions. The positions of structures can vary as necessary, for example, as designed for a modular assembly.

In some embodiments, target 932 can comprise a diffractive structure (e.g., a grating(s)). Target 932 can reflect, refract, diffract, scatter, or the like, radiation. For ease of discussion, and without limitation, radiation that interacts with a target will be termed scattered radiation throughout. The scattered radiation is collected by optical element 830. The scattered radiation comprises the reflection of the illumination beam (zero order) and a first diffraction order beam and a second diffraction order beam (e.g., positive and negative first order diffraction beams, positive and negative second order diffraction beams). For example, the scattered radiation may comprise ±first diffraction orders.

In some embodiments, detection system 906 may comprise an optical element 938, a reflective element (e.g., fold mirror) 940, an optical element 942 (e.g., a lens or lens system), a reflective element (e.g., a mirror) 944, an optical element 946, a reflective element (e.g., a mirror) 948, an optical element (e.g., a lens or lens system) 950, a reflective element (e.g., a mirror) 952, a reflective element (e.g., a mirror) 954, an optical element (e.g., a lens or lens system) 956, a beamsplitter 958, an optical element 976 (e.g., wedge), an optical element (e.g., a lens or lens system) 960, and a detector 962 (e.g., a photodetector). Beamsplitter 958 may direct a portion of the scattered radiation towards optical element 960. Beamsplitter 958 may direct another portion of the scattered radiation towards a wavefront sensor (not shown). Optical element 960 may be configured to focus the scattered radiation into detector 962. Detector 962 may be coupled with processor 908. Detector 962 may generate a signal beam as a function of the scattered direction. Processor 908 may form a two-dimensional image of target 932. Processor 908 may analyze the two-dimensional image to determine an overlay error.

In some embodiments, overlay systems described herein do not suffer from the coherent effect as there is a temporal difference between different acquisition of the signal beam.

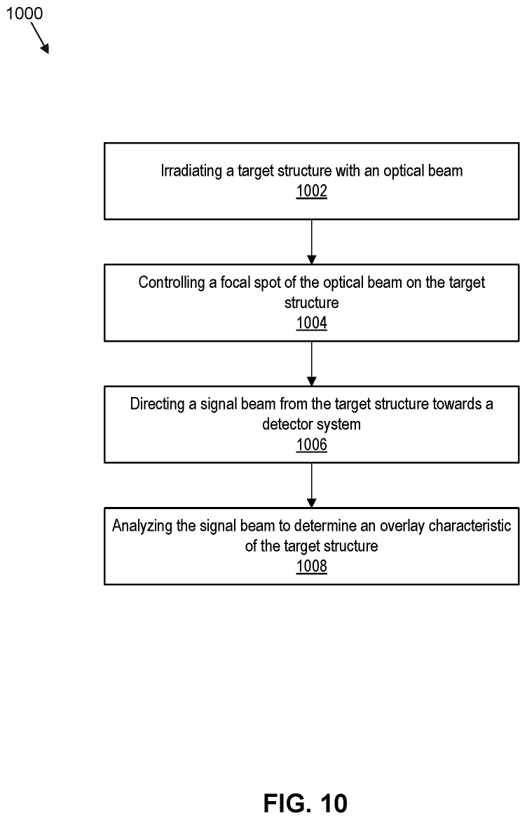

FIG. 10 shows method steps (e.g., using one or more processors) for performing a method 1000 including functions described herein, according to some embodiments. The method 1000 of FIG. 10 can be performed in any conceivable order and it is not required that all steps be performed. Moreover, the method steps of FIG. 10 described above merely reflect an example of steps and are not limiting.

Method 1000 illustrates a method for determining an overlay characteristic.

Method 1000 includes irradiating a target structure with an optical beam, as illustrated in step 1002.

The method also includes, controlling a focal spot of the optical beam on the target structure as illustrated in step 1004.

The method also includes directing a signal beam from the target structure towards a detector system, as illustrated in step 1006. The signal beam comprises at least a scattered beam generated from the target structure.

The method also includes analyzing the signal beam to determine an overlay characteristic of the target structure as illustrated in step 1008.

The embodiments may further be described using the following clauses:

1. A system comprising:
an illumination system configured to direct an optical beam to illuminate a target structure;
a scanning system configured to scan the optical beam and to control a size of a focal spot of the optical beam onto the target structure;
an optical system configured to maintain alignment with an optical axis of the system during scanning of the optical beam;
a detector system configured to detect a signal beam generated from the target structure during scanning of the optical beam, wherein the signal beam comprises at least a scattered beam generated from the target structure; and
a processor configured to analyze the detected signal beam to determine an overlay characteristic of the target structure.
   2. The system of clause 1, wherein the illumination system comprises:
a light source; and
a single mode fiber coupled to the light source, wherein the light source is a coherent light source.
   3. The system of clause 1, wherein the scanning system comprises a micro-electro mechanical system (MEMS) scanning mirror.
   4. The system of clause 1, wherein the scanning system comprises:
a first scanning mirror configured to scan the optical beam in a first direction; and
a second scanning mirror configured to scan the optical beam in a second direction, wherein the first direction is orthogonal to the second direction.
   5. The system of clause 4, wherein:
the first scanning mirror is configured to be actuated at a first speed;
the second scanning mirror is configured to be actuated at a second speed; and
the first speed is lower than the second speed.
   6. The system of clause 1, further comprising:
an optical element positioned within an illumination path and/or a detection path and is configured to correct aberrations in at least an image obtained by scanning the target structure using the scanning system.
   7. The system of clause 6, wherein:
the illumination system comprises a light source; and
the optical element is positioned in the illumination path between the light source and the target structure.
   8. The system of clause 6, wherein the optical element is positioned in the detection path after the target structure.
   9. The system of clause 8, further comprising:
another optical element configured to correct the aberrations; and
wherein the another optical element is positioned in the illumination path.
   10. The system of clause 6, wherein the optical element comprises a deformable mirror, a spatial light modulator, or an aberration corrector plate.
   11. The system of clause 6, further comprising:
an adaptive optical aberration control system,
wherein the optical element is coupled to the adaptive optical aberration control system.
   12. The system of clause 11, further comprising:
a sensor configured to measure a wavefront of the scattered beam; and
wherein the adaptive optical aberration control system is configured to control the optical element based on the measurement.
   13. The system of clause 1, further comprising:
an objective lens; and
wherein the optical system comprises a pupil relay system disposed between the scanning system and the objective lens.
   14. A method comprising:
irradiating a target structure with an optical beam;
controlling a focal spot of the optical beam on the target structure;
directing a signal beam from the target structure towards a detector system, wherein the signal beam comprises at least a scattered beam generated from the target structure; and
analyzing the signal beam to determine an overlay characteristic of the target structure.
   15. The method of clause 14, further comprising:
coupling a light source to a single mode fiber, wherein the light source is a coherent light source.
   16. The method of clause 14, further comprising:
scanning, using a first scanning mirror, the optical beam in a first direction at a first speed; and
scanning, using a second scanning mirror, the optical beam in a second direction at a second speed,
wherein the first speed is lower than the second speed, and
wherein the first direction is orthogonal to the second direction.
   17. The method of clause 14, further comprising:
using an optical element to correct for optical aberrations; and
positioning the optical element in an illumination path or a detection path.
   18. The method of clause 17, wherein the optical element comprises a deformable mirror, a spatial light modulator, or an aberration corrector plate.
   19. The method of clause 17, further comprising:
coupling the optical element to an optical aberration control system;
measuring a wavefront of the scattered beam; and
controlling, using the optical aberration control system, the optical element based on the measurement.
   20. A lithography apparatus comprising:
an illumination apparatus configured to illuminate a pattern of a patterning device;
a projection system configured to project an image of the pattern onto a substrate; and
a metrology system comprising:
an illumination system configured to direct an optical beam to illuminate a target structure,
a scanning system configured to scan the optical beam and to control a size of a focal spot of the optical beam onto the target structure;
an optical system configured to maintain alignment with an optical axis of the system during scanning of the optical beam;
a detector system configured to detect a signal beam generated from the target structure during scanning of the optical beam, wherein the signal beam comprises at least a scattered beam generated from the target structure; and
a processor configured to analyze the detected signal beam to determine an overlay characteristic of the target structure.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein can be considered as specific examples of the more general terms “substrate” or “target portion”, respectively. The substrate referred to herein can be processed, before or after exposure, in for example a track unit (a tool that typically applies a layer of resist to a substrate and develops the exposed resist) and/or a metrology unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

Although specific reference may have been made above to the use of embodiments of the present disclosure in the context of optical lithography, it will be appreciated that the present disclosure can be used in other applications, for example imprint lithography, and where the context allows, is not limited to optical lithography. In imprint lithography a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present disclosure is to be interpreted by those skilled in relevant art(s) in light of the teachings herein.

The terms “radiation,” “beam of radiation” or the like as used herein can encompass all types of electromagnetic radiation, for example, ultraviolet (UV) radiation (for example, having a wavelength 2 of 365, 248, 193, 157 or 126 nm), extreme ultraviolet (EUV or soft X-ray) radiation (for example, having a wavelength in the range of 5-20 nm such as, for example, 13.5 nm), or hard X-ray working at less than 5 nm, as well as matter beams, such as ion beams or electron beams. The terms “light,” “illumination,” or the like can refer to non-matter radiation (e.g., photons, UV, X-ray, or the like). Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some embodiments, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

While specific embodiments of the disclosure have been described above, it will be appreciated that embodiments of the present disclosure may be practiced otherwise than as described. The descriptions are intended to be illustrative, not limiting. Thus it will be apparent to one skilled in the art that modifications may be made to the disclosure as described without departing from the scope of the claims set out below.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of the protected subject matter should not be limited by any of the above-described exemplary embodiments, but should be defined only in accordance with the following claims and their equivalents.

1. A system comprising:
an illumination system configured to direct an optical beam to illuminate a target structure;
a scanning system configured to scan the optical beam and to control a size of a focal spot of the optical beam onto the target structure;
an optical system configured to maintain alignment with an optical axis of the system during scanning of the optical beam;
a detector system configured to detect a signal beam generated from the target structure during scanning of the optical beam, wherein the signal beam comprises at least a scattered beam generated from the target structure; and
a processor configured to analyze the detected signal beam to determine an overlay characteristic of the target structure.

2. The system of claim 1, wherein the illumination system comprises:
a light source; and
a single mode fiber coupled to the light source, wherein the light source is a coherent light source.

3. The system of claim 1, wherein the scanning system comprises a micro-electro mechanical system (MEMS) scanning mirror.

4. The system of claim 1, wherein the scanning system comprises:
a first scanning mirror configured to scan the optical beam in a first direction; and
a second scanning mirror configured to scan the optical beam in a second direction, wherein the first direction is orthogonal to the second direction.

5. The system of claim 4, wherein:
the first scanning mirror is configured to be actuated at a first speed;
the second scanning mirror is configured to be actuated at a second speed; and
the first speed is lower than the second speed.

6. The system of claim 1, further comprising:
an optical element positioned within an illumination path and/or a detection path and is configured to correct aberrations in at least an image obtained by scanning the target structure using the scanning system.

7. The system of claim 6, wherein:
the illumination system comprises a light source; and
the optical element is positioned in the illumination path between the light source and the target structure.

8. The system of claim 6, wherein the optical element is positioned in the detection path after the target structure.

9. The system of claim 8, further comprising:
another optical element configured to correct the aberrations; and
wherein the another optical element is positioned in the illumination path.

10. The system of claim 6, wherein the optical element comprises a deformable mirror, a spatial light modulator, or an aberration corrector plate.

11. The system of claim 6, further comprising:
an adaptive optical aberration control system,
wherein the optical element is coupled to the adaptive optical aberration control system.

12. The system of claim 11, further comprising:
a sensor configured to measure a wavefront of the scattered beam; and
wherein the adaptive optical aberration control system is configured to control the optical element based on the measurement.

13. The system of claim 1, further comprising:
an objective lens; and
wherein the optical system comprises a pupil relay system disposed between the scanning system and the objective lens.

14. A method comprising:
irradiating a target structure with an optical beam;
controlling a focal spot of the optical beam on the target structure;
directing a signal beam from the target structure towards a detector system, wherein the signal beam comprises at least a scattered beam generated from the target structure; and
analyzing the signal beam to determine an overlay characteristic of the target structure.

15. The method of claim 14, further comprising:
coupling a light source to a single mode fiber, wherein the light source is a coherent light source.
